(19) United States
(12) Patent Application Publication
(10) Pub. No.: US 2008/0017954 A1
(43) Pub. Date: Jan. 24, 2008

(54) Semiconductor device and semiconductor device manufacturing method

(76) Inventors: Jun Suzuki, Kyoto (JP); Kenji Yoneda, Kyoto (JP); Seiji Matsuyama, Hyogo (JP)

Correspondence Address: MCDERMOTT WILL & EMERY LLP, 600 13TH STREET, NW, WASHINGTON, DC, 20005-3096, US

(21) Appl. No.: 11/826,087

(22) Filed: Jul. 12, 2007

(30) Foreign Application Priority Data
Jul. 24, 2006 (JP) 2006-201052

(51) Int. Cl. H01L 23/58; H01L 21/31

(52) U.S. Cl. 257/637; 257/635; 438/761; 257/E23.002; 257/E21.04

(57) ABSTRACT

A capacitor insulating film composed of a layered film of first- to third-layer hafnium oxide films is formed on a lower electrode of a capacitor. The first- and third-layer hafnium oxide films have a composition ratio of oxygen to hafnium higher than the second-layer hafnium oxide film. Thus, the capacitor insulating film is composed of the first- and third-layer hafnium oxide films having greater barrier height and the second-layer hafnium oxide film having a higher dielectric constant, thereby attaining a capacitor having less leakage current and large capacity.

### BACKGROUND OF THE INVENTION

1. Field of the Invention

The present invention relates to semiconductor devices including a dielectric thin film as an element and methods for manufacturing it, and particularly relates to a semiconductor device including a hafnium oxide film as the dielectric thin film and a method for manufacturing it.

2. Description of the Prior Art

In association with recent progress in higher integration, semiconductor devices, such as semiconductor memory devices including capacitive elements for charge accumulation are miniaturized.

For example, in a capacitive structure of a DRAM (dynamic random access memory), a capacitor insulating film is formed between a lower electrode and an upper electrode basically. The cell capacity is in proportion to the dielectric constant of the capacitor insulating film and the effective capacitive area of the two opposed electrodes while being in inverse proportion to the thickness of the capacitor insulating film.

In association with miniaturization of the elements, however, the capacitor cell area is minimized to cause difficulty in ensuring necessary cell capacity. Accordingly, materials having a higher dielectric constant and capable of being thinned are being examined for application to the capacitor insulating films.

As an insulating film having a high dielectric constant, a tantalum oxide film (Ta₂O₅), and an aluminum oxide film (Al₂O₃) have been employed conventionally while high-dielectric metal oxide films, such as a zirconium oxide film (ZrO₂), a hafnium oxide film (HfO₂), and the like are employed in recent years.

When the dielectric constant is increased, the physical film thickness can be set greater to contemplate improvement on leakage current and withstand voltage. While, with a higher dielectric constant, the barrier height lowers in general to increase possibility of tunneling of electrons from a level higher than the Fermi level and possibility (tunneling current density) of flowing electrons into the conduction band in the insulating film over the barrier, thereby increasing leakage current.

Specifically, leakage current in a high dielectric metal oxide film, which has a high dielectric constant, depends on the physical film thickness of the film (dielectric constant) and the barrier height, and the barrier height lowers in general as the dielectric constant is increased. Accordingly, the film cannot be thinned physically, involving difficulty in increasing the cell capacity.

For tackling this problem, in a case using HfO₂ film as the capacitor insulating film, cell leakage current is suppressed and the cell capacity is increased by employing a three-layered structure in which an Al₂O₃ film having a low dielectric constant of 9 and a great barrier height of 2.0 eV is interposed between HfO₂ films having a dielectric constant of 25 and a barrier height of 1.0 to 1.5 eV or a multilayered structure of such HfO₂ films and such Al₂O₃ films (see Japanese Patent Application Laid Open Publication No. 2004-214602).

### SUMMARY OF THE INVENTION

In the case where a layered film composed of insulating films including different metal elements is formed by one film formation system, however, pealing off of a film from the reaction pipe and generation of particles of a by-product will occur frequently to lower the reliability and the yield of the capacitor and to increase variation in cell capacity and leakage current in a wafer.

The present invention has been made in view of the foregoing and has its principal object of providing a semiconductor device including a dielectric thin film as an element which has high reliability and excellent characteristics.

The inventors noticed through examination of film formation characteristics of hafnium oxide films that change in composition ratio of oxygen to hafnium in a film leads to stable formation of a hafnium oxide film having a greater barrier height. In detail, when a composition ratio of oxygen to hafnium (hereinafter referred to merely as oxygen ratio), which has been 1.2 in the conventional hafnium oxide films, is increased, a hafnium oxide film having a somewhat low dielectric constant and an increased barrier height can be formed stably.

In view of the foregoing and in order to solve the above problem, the present invention employs, in a semiconductor device including a dielectric thin film, a layered film of hafnium oxide films having different barrier heights as the dielectric thin film. The dielectric thin film in a layered structure of a hafnium oxide film having a high dielectric constant and a hafnium oxide film having great barrier height results in a semiconductor device including the dielectric thin film having high reliability and excellent characteristics. The different barrier heights are achieved by changing the oxygen ratio.

A semiconductor device in accordance with the present invention includes a dielectric thin film as an element, the dielectric thin film being composed of a layered film of a first hafnium oxide film and a second hafnium oxide film, wherein the second hafnium oxide film has barrier height greater than the first hafnium oxide film.

In a preferred embodiment, the second hafnium oxide film has a dielectric constant lower than the first hafnium oxide film.

In another preferred embodiment, the second hafnium oxide film has a composition ratio of oxygen to hafnium higher than the first hafnium oxide film.

In still another preferred embodiment, the second hafnium oxide film is formed by plasma oxidation of one principal face of the first hafnium oxide film.

In yet another preferred embodiment, the first hafnium oxide film is formed by hydrogen plasma treatment of one principal face of the second hafnium oxide film.

In another preferred embodiment, the second hafnium oxide film has a composition ratio of oxygen to hafnium of 2.1 or higher, and the first hafnium oxide film has a composition ratio of oxygen to hafnium of 2.0 or lower.

In still another preferred embodiment, the first hafnium oxide film or the second hafnium oxide film has a composition ratio of oxygen to hafnium which continuously varies in a film thickness direction.

In yet another preferred embodiment, the second hafnium oxide film has carbon concentration higher than the first hafnium oxide film.

Another semiconductor device in accordance with the present invention includes a dielectric thin film as a constitutional element, the dielectric thin film being composed of a layered film of a first hafnium oxide film, a second hafnium oxide film, and a third hafnium oxide film, wherein the first hafnium oxide film and the third hafnium oxide film have barrier height greater than the second hafnium oxide film.

In a preferred embodiment, the first hafnium oxide film and the third hafnium oxide film have a composition ratio of oxygen to hafnium higher than the second hafnium oxide film.

A semiconductor device manufacturing method in accordance with the present invention is a method for manufacturing a semiconductor device including as a constitutional element a dielectric thin film composed of a layered film of a first hafnium oxide film and a second hafnium oxide film, which includes the steps of: (a) forming the first hafnium oxide film by intruding into a reaction furnace an oxygen source gas and a hafnium source gas at a first flow rate ratio (a flow rate of the oxygen source gas per a flow rate of the hafnium source gas); and (b) forming the second hafnium oxide film by introducing into a reaction furnace the oxygen source gas and the hafnium source gas at a second flow rate ratio (a flow rate of the oxygen source gas per a flow rate of the hafnium source gas), wherein the second flow rate ratio is higher than the first flow rate ratio.

In a preferred embodiment, a composition ratio of oxygen to hafnium of the second hafnium oxide film is higher than a composition ratio of oxygen to hafnium of the first hafnium oxide film.

### BRIEF DESCRIPTION OF THE DRAWINGS

FIG. 1 is a graph showing a relationship between the dielectric constant and the barrier height of hafnium oxide films having different barrier heights in the present invention.

FIG. 2 is a graph showing a relationship between the oxygen ratio and the dielectric constant of the hafnium oxide films having different barrier heights in the present invention.

FIG. 3 is a diagram showing a method for forming the hafnium oxide films having different oxygen ratios in Embodiment 1 of the present invention.

FIG. 4 is a graph showing a relationship between the flow rate ratio of supplied reaction gases per cycle and the oxygen ratio in a film in Embodiment 1 of the present invention.

FIG. 5 is a graph showing a relationship between the equivalent oxide thickness and leakage current in Embodiment 1 of the present invention.

FIG. 6 is a sectional view schematically showing a structure of a capacitor including a dielectric thin film in a three-layered structure in Embodiment 1 of the present invention.

FIG. 7 is a distribution graph indicating the oxygen ratio in the film thickness direction of a dielectric thin film composed of the hafnium oxide films in the three-layered structure in Embodiment 1 of the present invention.

FIG. 8 is a graph showing a relationship between the cell capacity and the dielectric constant or the film thickness of a second layer in Embodiment 1 of the present invention.

FIG. 9A and FIG. 9B are sectional views schematically showing steps of a method for manufacturing a capacitor including a capacitor insulating film in a three-layered structure in Embodiment 2 of the present invention.

FIG. 10 is a distribution diagram indicating the oxygen ratio in the film thickness direction of the dielectric thin film composed of the hafnium oxide films in the three-layered structure in Embodiment 2 of the present invention.

FIG. 11A to FIG. 11B are sectional views schematically showing steps of a method for manufacturing a capacitor including the capacitor insulating film in the three-layered structure in Embodiment 2 of the present invention.

FIG. 12 is a diagram showing a construction of a semiconductor substrate treatment system in Embodiment 3 of the present invention.

FIG. 13A and FIG. 13B are graphs showing relationships between pre-heating temperature and the carbon concentration or the oxygen ratio of a hafnium oxide film in Embodiment 3 of the present invention.

FIG. 14 is a graph showing a relationship between the pre-heating temperature and the film formation rate in Embodiment 3 of the present invention.

FIG. 15 is a graph showing a relationship between the equivalent oxide thickness and leakage current in Embodiment 3 of the present invention.

### DESCRIPTION OF THE PREFERRED EMBODIMENTS

Embodiments of the present invention will be described below with reference to the accompanying drawings. Wherein, the same reference numerals are assigned to elements having substantially the same functions in the drawings for the sake of simplified description. It should be noted that the present invention is not limited to the following embodiments.

### Embodiment 1

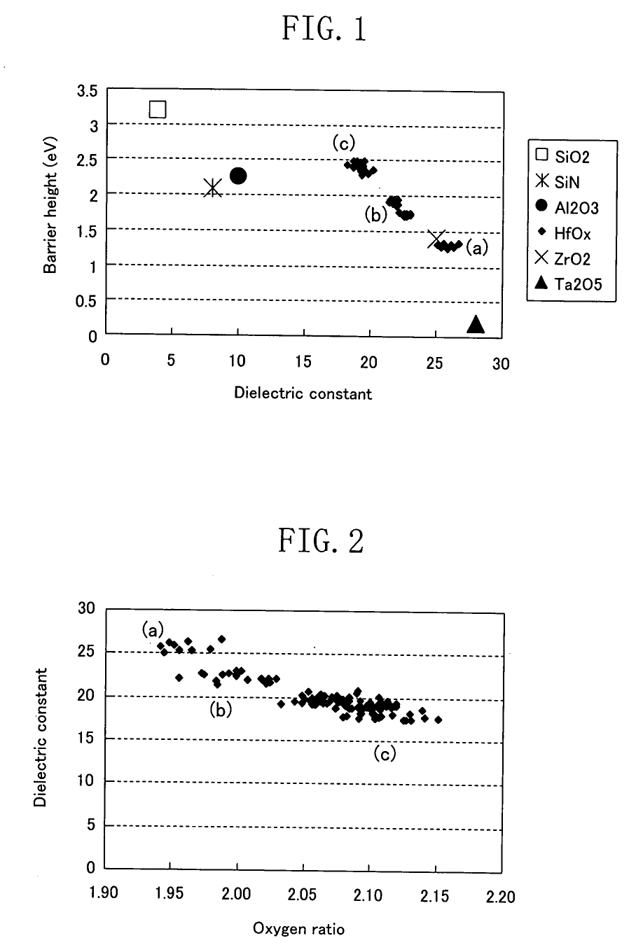

FIG. 1 is a graph showing a relationship between the dielectric constant (relative dielectric constant) and the barrier height of hafnium oxide films having different barrier heights in the present invention. In FIG. 1, (a) indicates a conventional hafnium oxide film having a dielectric constant of 25 to 28 and a barrier height of approximately 1.4 V while (b) and (c) indicate hafnium oxide films having greater barrier heights than (a). The barrier height of the hafnium oxide film (c), is approximately 2.4 to 2.5 eV, which is greater than the barrier heights of an Al₂O₃ film and a silicon nitride film (SiN), and in addition, the dielectric constant thereof is higher than the dielectric constants of an Al₂O₃ film and a silicon nitride film (SiN). As shown in FIG. 1, the hafnium oxide films of the present invention show a tendency that the dielectric constants thereof lowers as the barrier heights thereof are increased.

FIG. 2 is a graph showing a relationship between the oxygen ratio and the dielectric constant of the hafnium oxide films (a), (b), and (c) indicated in FIG. 1 of which barrier heights are different from one another. As shown in FIG. 2, an increase in oxygen ratio lowers the dielectric constants, namely, increases the barrier heights. When the oxygen ratio is approximately 2.1, the dielectric constant becomes below 20 while the barrier height becomes approximately 2.4 eV, attaining a hafnium oxide film having a higher dielectric constant and greater barrier height than an Al₂O₃ film and a silicon nitride film.

The oxygen ratios of the hafnium oxide films were measured by an EPMA (electron probe microanalizer) calibrated by HR-RBS (high resolution Rutherford backscattering spectroscopy).

When a dielectric thin film is composed of a layered film of the hafnium oxide films having different barrier heights, namely, of a hafnium oxide film having a high dielectric constant and a hafnium oxide film having great barrier height, the dielectric thin film can have large capacity and less leakage current. When the thus composed dielectric thin film is used as, for example, a capacitor insulating film of a capacitor, a gate insulating film of a MIS transistor, or the like, a semiconductor device can be attained which has high reliability and excellent characteristics.

The layered film may have a layered structure of two, three, or more layers according to the purpose. For example, when a dielectric thin film used as a capacitor insulating film of a capacitor has a three-layered structure in which a hafnium oxide film having a high dielectric constant (a low oxygen ratio) is interposed between hafnium oxide films having the same great barrier height (a high oxygen ratio), the capacitor can have less leakage current, large capacity, and capacitor characteristics excellent in symmetry. Alternatively, in the case where leakage current characteristics are different between positive and negative voltages, when the dielectric thin film is allowed to have a two-layered structure of a hafnium oxide film having a high dielectric constant (a low oxygen ratio) and a hafnium oxide film having great barrier height (a high oxygen ratio), the capacitor has large capacity with leakage current reduced in a given direction.

A method for forming hafnium oxide films having different barrier heights, that is, different oxygen ratios in the present invention will be described next.

The oxygen ratio of a hafnium oxide film depends on temperature at film formation and the flow rate ratio of supplied reaction gases. Change in film formation temperature in a chamber, however, is liable to cause pealing off, thereby generating particles to lower yields. Further, repetition of temperature rise and drop of the heater prolongs time required for film formation to lower the throughput of the instrument. Or, in the case using a single-wafer type film formation system, parallel provision of chambers capable of coping with respective film formation temperatures is uneconomical. In view of these, the hafnium oxide films having different oxygen ratios in the present invention are formed with the flow rate ratio changed.

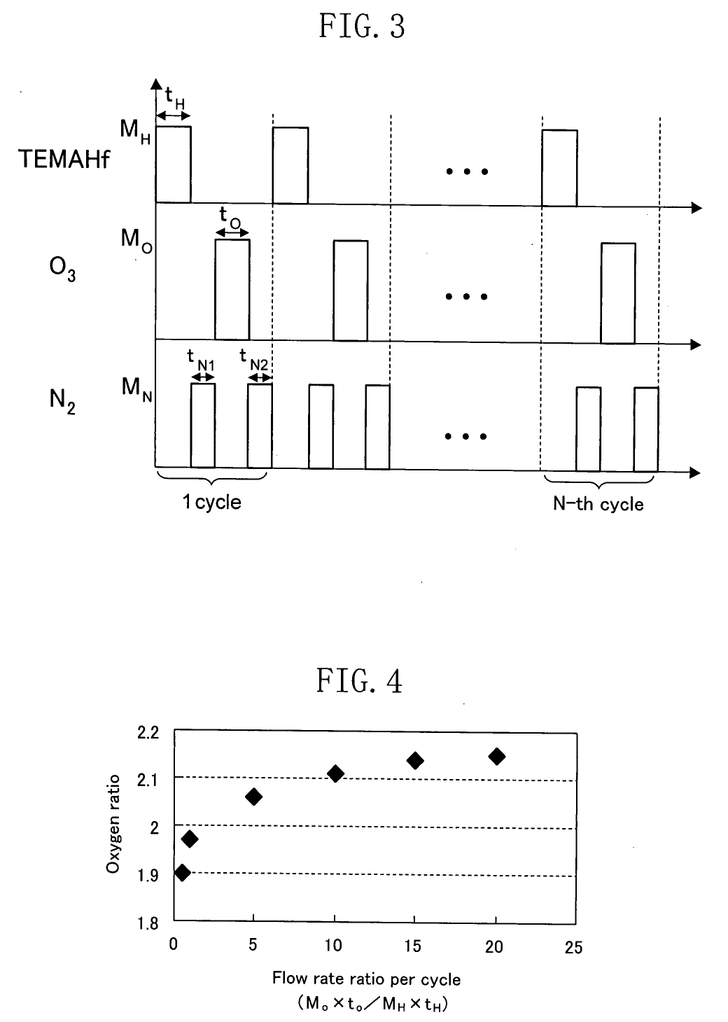

FIG. 3 is a diagram showing a method for forming hafnium oxide films having different oxygen ratios by employing ALD (automatic layer deposition). In ALD, TEMAHf (tetrakis(ethylmethylamino)hafnium) as a hafnium source gas, O₃ as an oxygen source gas, and N₂ as an inert gas are supplied onto a wafer one by one alternately so that the respective atoms are deposited by only surface reaction on one atom layer basis. Detailed description will be followed with reference to FIG.3.

First, TEMAHf as a hafnium source gas is allowed to flow at a flow rate of M_{H} (typically, 0.1 to 0.3 g/min) for a time period of t_{H} (typically, 30 to 180 seconds). In this step, the temperature of the furnace is set to 150 to 300° C. while the pressure of the furnace is set to 500 Pa or lower to cause surface deposition of Hf on the wafer.

Next, N₂ purge is performed for discharging TEMAHf remaining in the furnace. The purge in this step is performed at a flow rate M_{N} of 1.0 to 5.0 slm for a time period t_{N1} of 1 to 30 seconds at the pressure of 50 Pa or lower. After N₂ purge, vacuuming is performed. N₂ purge and vacuuming may be repeated over one time in this step.

Subsequently, O₃ as an oxygen source gas is supplied at a flow rate of M_{O} (typically, 1.0 to 5.0 slm) for a time period of to (typically, 30 to 300 seconds) with the furnace pressure set to 500 Pa or lower to cause reaction of oxygen to Hf deposited on the wafer.

Thereafter, N₂ purge is performed for discharging O₃ remaining in the furnace. The purge in this step is performed at a flow rate M_{N} of 1.0 to 5.0 slm for a time period t_{N2} of 1 to 30 seconds at the pressure of 50 Pa or lower. After N₂ purge, vacuuming is performed. N₂ purge and vacuuming may be repeated over one time in this step.

The above-described cyclic pulse purge is repeated N times until a desired film thickness is attained.

In the method for forming hafnium oxide films by ALD, when the flow rate ratio of the ozone gas to the hafnium gas per cycle (M_{O}×t_{O}/M_{H}×t_{H}) is changed between 0.5 to 20, the oxygen ratio of the thus formed films varies between 1.9 and 2.15, as shown in FIG. 4.

In other words, change in oxygen ratio of a hafnium oxide film between 1.9 and 2.15 changes the barrier height of the hafnium oxide film between 1.4 and 2.5 eV.

In the case where a single-layer hafnium oxide film is employed as the dielectric thin film, when the hafnium oxide film has a high dielectric constant for increasing the capacity, the barrier height lowers, as shown in FIG. 1, to increase leakage current. In reverse, when the hafnium oxide film has great barrier height for reducing leakage current, the dielectric constant becomes low, attaining no desired capacity. In sum, the capacity and the leakage current fall in an antinomy relationship in which an increase in one of them sacrifices the other.

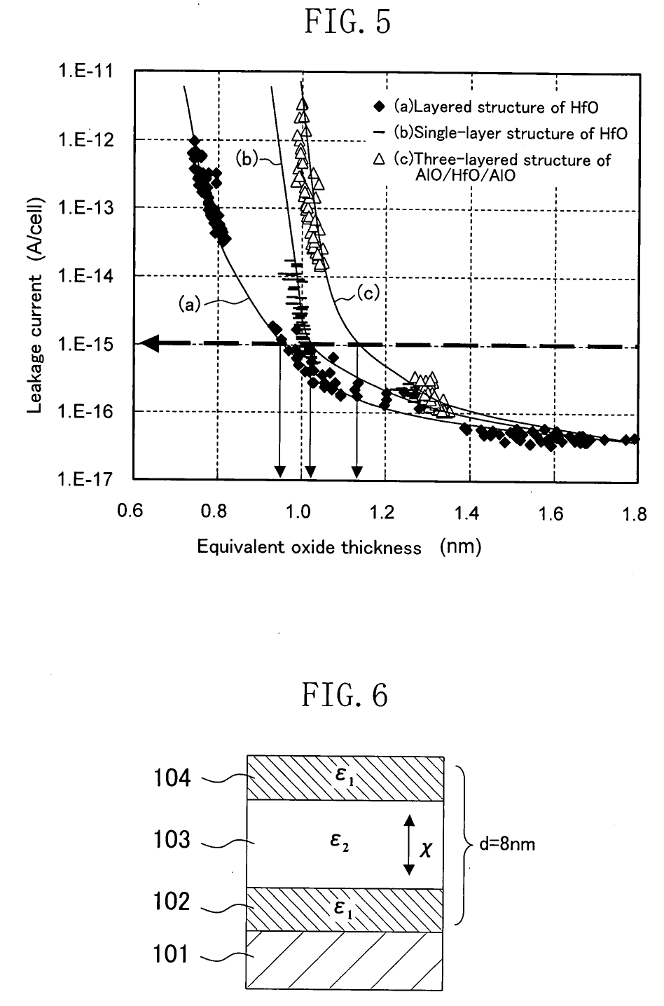

FIG. 5 is a graph showing relationships between the film thicknesses (equivalent oxide thicknesses) of dielectric thin films and leakage current. For example, when the dielectric thin film has a single-layer structure of a hafnium oxide file having an oxygen ratio of 2.05 to 2.1 (a dielectric constant of 21), the equivalent oxide thickness must be approximately 1.05 nm or larger according to the graph (b) in FIG. 5 in order to satisfy the leakage current standard, 1.0E-05 (A/cell) at a voltage between ±8 V. Alternatively, when the dielectric thin film has a three-layered structure of aluminum oxide film/hafnium oxide file/aluminum oxide film, the equivalent oxide thickness must be 1.1 nm or larger according to the graph (c) in FIG. 5 in order to satisfy the same leakage current standard.

In contrast, when the dielectric thin film has a three-layered structure, for example, in which a hafnium oxide film having a dielectric constant of 26 is interposed between hafnium oxide films having a dielectric constant of 17, the equivalent oxide thickness can be reduced to approximately 0.95 nm according to the graph (a) in FIG. 5 in order to satisfy the same leakage current standard, thereby increasing the capacity of the dielectric thin film. When the equivalent oxide thickness is reduced 0.1 nm, the capacity of the dielectric thin film increases approximately 10%.

FIG. 6 is a sectional view schematically showing a structure of a capacitor in which a first- to third-layer hafnium oxide films 102, 103, 104 are formed on a lower electrode 101 of the capacitor (an upper electrode is not shown).

As shown in FIG. 6, the first-layer hafnium oxide film 102 having a thickness of approximately 2.0 nm is formed on the lower electrode 101 of the capacitor with the flow rate ratio per cycle set to 20 so as to attain an oxygen ratio of 2.15. Next, the second-layer hafnium oxide film 103 having a thickness of approximately 4.0 nm is formed on the first-layer hafnium oxide film 102 with the flow rate ratio per cycle set to 0.5 so as to attain an oxygen ratio of 1.9, and then, the third-layer hafnium oxide film 104 having a thickness of approximately 2.0 nm is formed on the second-layer hafnium oxide film 103 under the same conditions as those in formation of the first-layer hafnium oxide film 102.

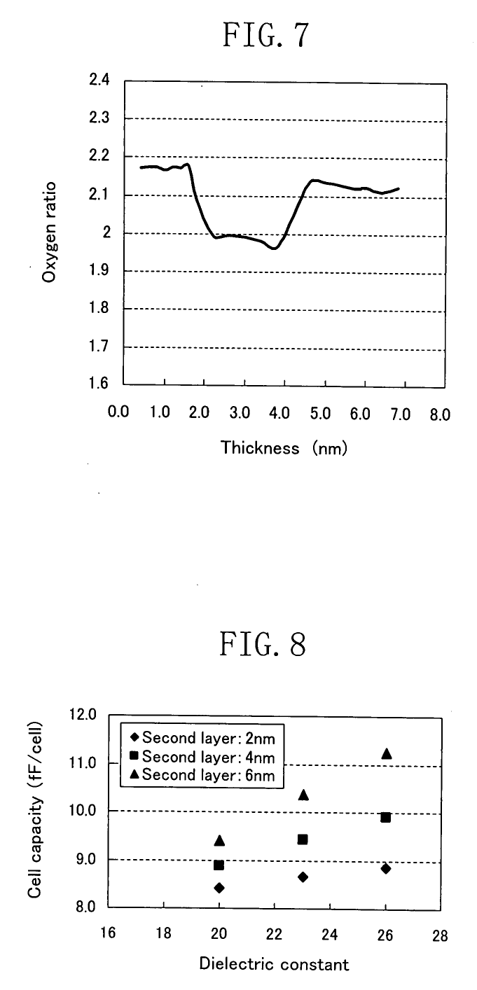

FIG. 7 indicates a result obtained by measuring by HR-RBS the oxygen ratio in the film thickness direction of a dielectric thin film composed of the thus formed first- to third-layer hafnium oxide films.

FIG. 8 is a graph showing the cell capacity in the case where the dielectric constant ε₂ and the film thickness χ of the second-layer hafnium oxide film are changed with the film thickness d of the capacitor insulating film of a capacitor set to 8 nm and the dielectric constant ε₁ of the first- and third-layer hafnium oxide films set to 17.

Given that C₀ is the cell capacitor when the capacity insulating film (film thickness: d) of the capacitor is composed of a single layer of the first- or third-layer hafnium oxide film (dielectric constant: ε₁), the cell capacity C of the capacity insulating film (film thickness: d) in the three-layered structure of the first- to third-layer hafnium oxide films is obtained from the following equation (1). As can be understood from FIG. 8 and the equation (1), when the film thickness χ and the dielectric constant ε₂ of the second-layer hafnium oxide film are increased, the cell capacity thereof increases ε₂/ε₁ times the cell capacity C₀ of the single-layer hafnium oxide film to a maximum.

$$C = \frac{1}{1 - ( 1 - \frac{{ɛ}_{1}}{{ɛ}_{2}} ) \frac{x}{d}} {C}_{0} \qquad Equation ( 1 )$$

Although ALD is employed in the method for forming hafnium oxide films in the present embodiment, the present invention is not limited thereto and may employ CVD, for example. Particularly, in the case where the films are formed at a temperature of 300° C. or higher, employment of CVD is desirable. When employing CVD, it is preferable that the flow rate ratio of the oxygen source gas to the hafnium source gas for forming the first- and third-layer films is set to 10 while the flow rate ratio thereof for forming the second-layer film is set to 1.

TEMAHf and O₃ are used as the hafnium source gas and the oxygen source gas, respectively, in the present embodiment, but the use of an organic hafnium source gas, such as HfCl₄ (hafnium chloride), Hf[N(CH₃)₂]₄, or the like as the hafnium source gas and H₂O, N₂O, or the like as the oxygen source gas attains the same effects.

It is noted that the lower electrode 101 and the upper electrode (not shown) of the capacitor shown in FIG. 6 is preferably made of titanium nitride (TiN), tantalum nitride (TaN), ruthenium, tungsten, or the like.

In addition, the capacitor insulating film of the capacitor shown in FIG. 6 has a three-layered structure composed of the hafnium oxide films having different oxygen ratios, but may have a two-layered structure. Specifically, in the case where the upper electrode must be formed at a temperature of 300° C. or lower in view of variation in composition of the hafnium oxide films though the lower electrode 101 may be formed at a temperature of 400° C. or higher, in other words, in the case where the upper electrode and the lower electrode have a MIM (metal-insulator-metal) structure of different metals, the capacitor insulating film may have a two-layered structure of a hafnium oxide film having great barrier height (an oxygen ratio of approximately 2.1, for example) and a hafnium oxide film having a high dielectric constant (an oxygen ratio of approximately 1.9, for example). Similarly, in the case where the upper electrode and the lower electrode have a MIS (meta-insulator-semiconductor) structure in which the surface area is increased with the use of silicon grain in the underlay, the capacitor insulating film may have the above two-layered structure.

### Embodiment 2

While the layered film of the hafnium oxide films having different oxygen ratios are formed by ALD or CVD in Embodiment 1, Embodiment 2 describes another method for forming a layered film of hafnium oxide films having different oxygen ratios, in which one principal face of a hafnium oxide film are subjected to plasma oxidation or hydrogen plasma treatment to change a part of the hafnium oxide film to a region having an oxygen ratio different from the other part.

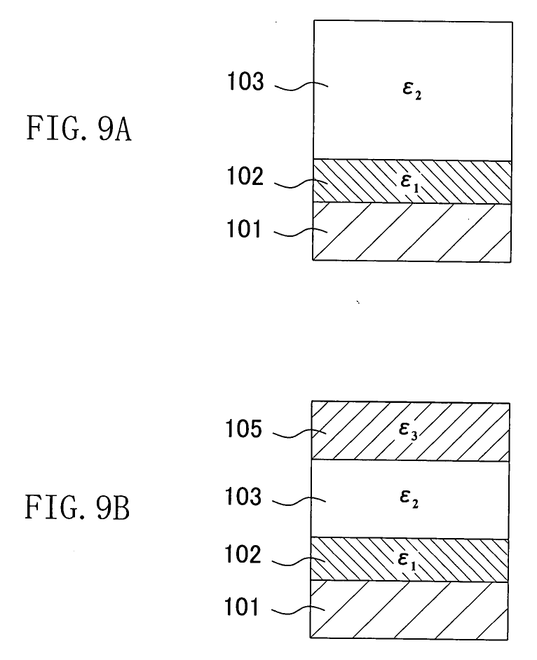

FIG. 9A and FIG.9B are sectional view schematically showing a method for fabricating a capacitor including a capacitor insulating film in a three-layered structure composed of hafnium oxide films having different oxygen ratios in the present embodiment.

First, as shown in FIG. 9A, a hafnium oxide film 102 having a thickness of approximately 2 nm and great barrier height, for example, an oxygen ratio of approximately 2.1 is formed as a first layer on the lower electrode 101 of the capacitor, and then, a hafnium oxide film 103 having a thickness of approximately 6 nm and a dielectric constant higher than the first layer, for example, an oxygen ratio of approximately 1.9 is formed as a second layer thereon.

Next, the surface of the second-layer hafnium oxide film 103 is subjected to plasma oxidation at a temperature of 250 to 400° C. This forms a third layer 105 having a thickness of 1 to 3 nm and an oxygen ratio of 2.1 or higher in the surface portion of the hafnium oxide film 103.

The film thickness as well as the oxygen ratio of the third layer 105 having an oxygen ratio of 2.1 or higher can be adjusted by adjusting the temperature, the oxygen flow rate, and the plasma power in plasma oxidation.

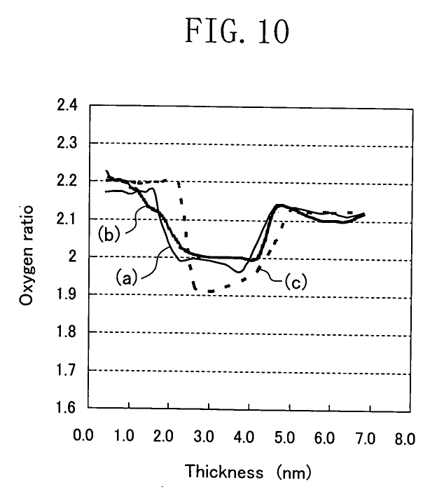

FIG. 10 is a graph showing results obtained by measuring by HR-RBS the oxygen ratios in the film thickness direction of the three-layered capacitor insulating films formed by the methods in accordance with the present invention, wherein (a) indicates the case where the film is formed by the method in Embodiment 1 and (b) indicates the case where the film is formed by the method in the present embodiment. The film formed by the method in the present embodiment shows a characteristic that the oxygen ratio decreases continuously from the third layer 105 to the second layer 103.

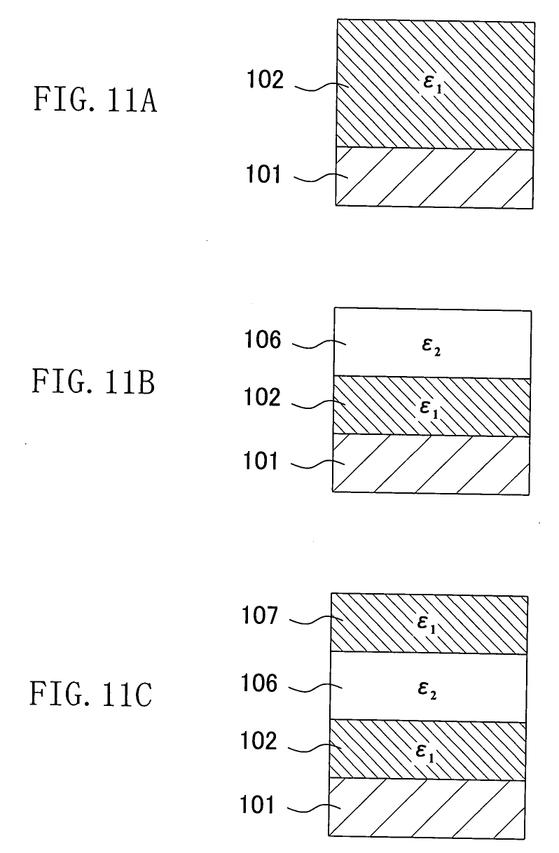

FIG. 11A to FIG. 11C are sectional views schematically showing another method for fabricating a capacitor including a capacitor insulating film in a three-layered structure of hafnium oxide films having different oxygen ratios in the present embodiment.

First, as shown in FIG. 11A, a hafnium oxide film 102 having a film thickness of 6 nm and great barrier height, for example, an oxygen ratio of 2.0 or higher is formed as a first layer on the lower electrode 101 of the capacitor.

Next, as shown in FIG. 11B, the surface of the hafnium oxide film 102 is subjected to hydrogen plasma treatment. This reduces the surface of the hafnium oxide film 102 to form a second layer 106 having a thickness of approximately 1 to 3 nm and an oxygen ratio of 2.0 or lower.

The film thickness as well as the oxygen ratio of the second layer 106 having an oxygen ratio of 2.0 or lower can be adjusted by adjusting the temperature, the hydrogen flow rate, and the plasma power in hydrogen plasma treatment. Alternatively, the surface of the hafnium oxide film can be reduced by thermal treatment in a hydrogen atmosphere rather than hydrogen plasma treatment, which can attain the same effects.

Subsequently, as shown in FIG. 11C, a hafnium oxide film 107 having a film thickness of approximately 2 nm and great barrier height, for example, having an oxygen ratio of 2.0 or higher is formed as a third layer on the second layer 106.

The graph (c) in FIG. 10 indicates the oxygen ratio in the film thickness direction of a capacitor insulating film in the three-layered structure formed by the above method, and the thus formed capacitor insulating film shows a characteristic that the oxygen ratio decreases continuously from the first layer 102 to the second layer 106.

In the present embodiment, as well as in Embodiment 1, the equivalent oxide thickness can be reduced to approximately 0.95 nm, which satisfies the leakage current standard, 1.0E-15 (A/cell). As a result, the capacity of the dielectric thin film increases while leakage current is reduced.

### Embodiment 3

The present embodiment describes a method for forming a layered film of hafnium oxide films having different oxygen ratios by ALD or CVD, as a modified example of Embodiment 1.

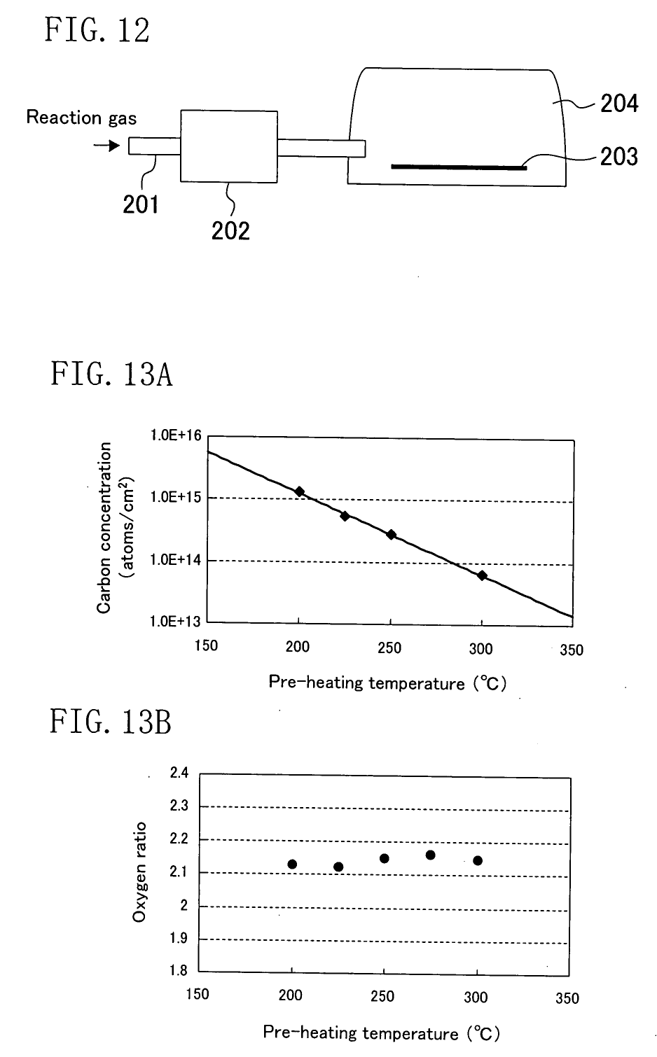

FIG. 12 is a diagram showing a construction of a semiconductor substrate treatment system in the present embodiment which includes a reaction furnace 204 and a pre-heating chamber 202 for thermal decomposition of TEMAHf as a hafnium source gas before it is supplied to the reaction furnace 204.

FIG. 13A and FIG. 13B shows the carbon concentration and the oxygen ratio of a hafnium oxide film, respectively, with respect to thermal decomposition temperature of the pre-heating chamber 202. As shown in FIG. 13A and FIG. 13B, the oxygen ratio less depends on the thermal decomposition temperature while the carbon concentration lowers exponentially as the thermal decomposition temperature is increased.

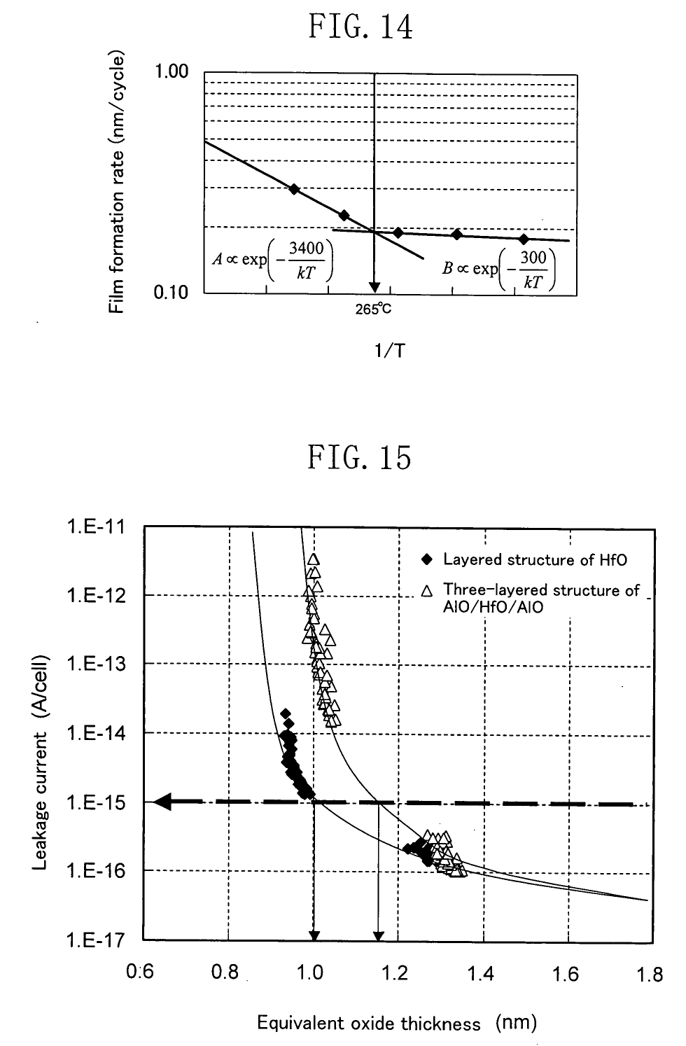

As also shown in FIG. 14, the film formation rate with respect to the thermal decomposition temperature increases sharply as the thermal decomposition temperature is increased from around 256° C.

This means that the activation energy Ea increases from around 265° C. according to Arrhenius' equation (2). Since a material having larger activation energy is more stable in general, the reliability of the dielectric thin film, such as leakage current, withstand voltage, TDDB (time-dependent dielectric breakdown), and the like might increase.

$$DepoRate ∞ exp ( - \frac{Ea}{kT} ) \qquad Equation ( 2 )$$

Wherein: k is a Boltzmann's factor; and Ea is an activation energy As the thermal decomposition temperature is increased, however, leakage current increases and TDDB is degraded. In detail, an increase in thermal decomposition temperature generates a boundary of grains formed by vapor growth in the hafnium oxide films, so that the thus generated grain boundary serves as a leak path that allows leakage current to flow, thereby inviting an increase in leakage current and degradation of TDDB.

In contrast, when the carbon concentration of a hafnium oxide film is lowered as far as possible by increasing the thermal decomposition temperature, namely, when the hafnium oxide film has high hafnium concentration, the capacity of the dielectric thin film increases. This means that the capacity and the leakage current fall in an antinomy relationship.

Description will be given with reference to FIG. 3 again to a method for forming hafnium oxide films having different oxygen ratios in the present embodiment. Wherein, description of the same steps as those in Embodiment 1 is omitted.

For forming the first-layer hafnium oxide film, TEMAHf as a hafnium source gas is allowed to flow at a flow rate M_{H} of 0.1 to 0.3 g/min for a time period t_{H} of 30 to 180 seconds with the temperature of the reaction furnace 204 and the pre-heating chamber 202 set to the same temperature of approximately 150 to 250° C. and the furnace pressure set to 500 Pa or lower to cause surface deposition of Hf on the wafer.

Next, followed by discharge of TEMAHf remaining in the furnace, O₃ as an oxygen source is allowed to flow at a flow rate M_{O} of 1.0 to 5.0 slm for a time period to of 30 to 300 seconds with the furnace pressure set to 500 Pa or lower to cause a reaction of oxygen with Hf deposited on the wafer.

The above described cyclic pulse purge is repeated until a desired film thickness of the first layer is obtained. For example, for forming the first layer having a thickness of 2 nm, the cycle is repeated 10 times on the assumption that the film formation rate is 0.2 nm per cycle.

Before formation of the second layer and after formation of the first layer, the temperature of the pre-heating chamber 202 is raised to approximately 250 to 400° C. During temperature rise of the pre-heating chamber 202, the reaction furnace 204 is N₂ purged.

After the temperature of the pre-heating chamber 202 reaches the predetermined value, the above film formation sequence is repeated to form the second layer having a thickness of, for example, approximately 4 nm and lower carbon concentration, namely, higher hafnium concentration than the first layer.

In the step of forming the third layer, the temperature of the pre-heating chamber 202 is lowered to the temperature of the reaction furnace 204 first. During this time, the reaction furnace 204 is N₂ purged. After the temperature of the pre-heating chamber 202 becomes equal to the temperature of the reaction furnace 204, the third layer having a thickness of, for example, approximately 2 nm is formed under the same conditions as those in forming the first layer.

FIG. 15 shows a relationship between leakage current (A/cell) and the equivalent oxide thickness of a dielectric thin film (a capacitor insulating film of a DRAM capacitor) in a three-layered structure of hafnium oxide films formed by the method in accordance with the present embodiment.

Referring to the conventional three-layered structure of aluminum oxide film/hafnium oxide film/aluminum oxide film, the equivalent oxide thickness must be approximately 1.1 nm or larger for satisfying the leakage current standard, 1.0E-15 (A/cell). In contrast, the present embodiment reduces the equivalent oxide thickness to 1.0 nm, thereby easily securing the cell capacity.

The pre-heating chamber 202 is provided in the present embodiment, but an external plasma treatment chamber capable of plasma-decomposing the hafnium source gas may be provided, rather than the pre-heating chamber 202, for plasma-decomposing the hafnium source gas in forming the second layer.

In the present invention, a layered film of hafnium oxide films having different barrier heights is used as a dielectric thin film composing a semiconductor device so that the dielectric thin film is composed of a layered film of a hafnium oxide film having a high dielectric constant and a hafnium oxide film having great barrier height. This attains a semiconductor device including a dielectric thin film having high reliability and excellent characteristics.

Further, the hafnium oxide films having different barrier heights can be formed stably by changing the oxygen ratio to hafnium, thereby manufacturing a semiconductor device including a dielectric thin film having high reliability and excellent characteristics with yields increased.

What is claimed is:

1. A semiconductor device, comprising:
a dielectric thin film as a constitutional element, the dielectric thin film being composed of a layered film of a first hafnium oxide film and a second hafnium oxide film,
wherein the second hafnium oxide film has barrier height greater than the first hafnium oxide film.

2. The semiconductor device of claim 1,
wherein the second hafnium oxide film has a dielectric constant lower than the first hafnium oxide film.

3. The semiconductor device of claim 1,
wherein the second hafnium oxide film has a composition ratio of oxygen to hafnium higher than the first hafnium oxide film.

4. The semiconductor device of claim 1,
wherein the second hafnium oxide film is formed by plasma oxidation of one principal face of the first hafnium oxide film.

5. The semiconductor device of claim 1,
wherein the first hafnium oxide film is formed by hydrogen plasma treatment of one principal face of the second hafnium oxide film.

6. The semiconductor device of claim 3,
wherein the second hafnium oxide film has a composition ratio of oxygen to hafnium of 2.1 or higher, and
the first hafnium oxide film has a composition ratio of oxygen to hafnium of 2.0 or lower.

7. The semiconductor device of claim 4,
wherein the first hafnium oxide film or the second hafnium oxide film has a composition ratio of oxygen to hafnium which continuously varies in a film thickness direction.

8. The semiconductor device of claim 5,
wherein the first hafnium oxide film or the second hafnium oxide film has a composition ratio of oxygen to hafnium which continuously varies in a film thickness direction.

9. The semiconductor device of claim 1,
wherein the second hafnium oxide film has carbon concentration higher than the first hafnium oxide film.

10. A semiconductor device, comprising:
a dielectric thin film as a constitutional element, the dielectric thin film being composed of a layered film of a first hafnium oxide film, a second hafnium oxide film, and a third hafnium oxide film,
wherein the first hafnium oxide film and the third hafnium oxide film have barrier height greater than the second hafnium oxide film.

11. The semiconductor device of claim 10,
wherein the first hafnium oxide film and the third hafnium oxide film have a composition ratio of oxygen to hafnium higher than the second hafnium oxide film.

12. The semiconductor device of claim 11,
wherein the composition ratio of oxygen to hafnium of the first hafnium oxide film is equal to that of the third hafnium oxide film.

13. The semiconductor device of claim 1,
wherein the dielectric thin film composes a capacitor insulating film of a capacitor or a gate insulating film of a MIS transistor.

14. The semiconductor device of claim 10,
wherein the dielectric thin film composes a capacitor insulating film of a capacitor or a gate insulating film of a MIS transistor.

15. A method for manufacturing a semiconductor device including as a constitutional element a dielectric thin film composed of a layered film of a first hafnium oxide film and a second hafnium oxide film, comprising the steps of:
(a) forming the first hafnium oxide film by intruding into a reaction furnace an oxygen source gas and a hafnium source gas at a first flow rate ratio (a flow rate of the oxygen source gas per a flow rate of the hafnium source gas); and
(b) forming the second hafnium oxide film by introducing into a reaction furnace the oxygen source gas and the hafnium source gas at a second flow rate ratio (a flow rate of the oxygen source gas per a flow rate of the hafnium source gas),
wherein the second flow rate ratio is higher than the first flow rate ratio.

16. The method of claim 15,
wherein a composition ratio of oxygen to hafnium of the second hafnium oxide film is higher than a composition ratio of oxygen to hafnium of the first hafnium oxide film.

17. The method of claim 15,
wherein the first flow rate ratio is 1 or lower while the second flow rate ratio is 5 or higher.

18. The method of claim 15,
wherein the step (a) includes a step of pre-heating the hafnium source gas, and
the hafnium source gas thermal-decomposed by the pre-heating step is introduced into the reaction furnace in the step (a).

19. The method of claim 15,
wherein the step (b) includes a step of plasma-decomposing the hafnium source gas, and
the thus plasma-decomposed hafnium source gas is introduced into the reaction furnace in the step (b).
